(19) United States
(12) Patent Application Publication
(10) Pub. No.: US 2012/0273786 A1
(43) Pub. Date: Nov. 1, 2012

(54) ORGANIC SURFACE PROTECTIVE LAYER COMPOSITION AND METHOD FOR PROTECTING ORGANIC SURFACE

(75) Inventor: Isao Yahagi, Tsuchiura-shi (JP)

(73) Assignee: SUMITOMO CHEMICAL COMPANY, LIMITED, Chuo-ku, Tokyo (JP)

(21) Appl. No.: 13/503,973

(22) PCT Filed: Oct. 27, 2010
(86) PCT No.: PCT/JP2010/069025

§ 371 Date: Jul. 9, 2012

(30) Foreign Application Priority Data
Oct. 27, 2009 (JP) 2009-246688

(51) Int. Cl. C09D 5/00; H01L 29/786; H01L 21/4757; H01L 21/47

(52) U.S. Cl. 257/57; 438/694; 257/66; 106/287.18; 438/99; 257/40; 257/E29.273; 257/E21.492; 257/E21.49

(57) ABSTRACT

The problem to be solved by the present invention is to provide such an organic surface protective layer composition that a thin and uniform protective layer can be formed on a surface of an organic layer, that the formed protective layer can easily be removed by etching, and that it can inhibit the alteration of the organic compound presenting in the surface of the organic layer exposed by the etching. Means for solving the problem is an organic surface protective layer composition containing (A) a metal alkoxide, (B) a stabilizer for the metal alkoxide and (C) an organic solvent capable of dissolving the metal alkoxide.

### TECHNICAL FIELD

The present invention relates to a protective layer for protecting a surface of an organic substance, particularly a surface of an organic layer constituted of an organic substance, from physical or chemical action applied from surroundings, and a composition for forming the protective layer thereof.

### BACKGROUND ART

In organic devices such as organic thin film transistors and organic EL devices, functional layers, such as an insulating layer, a semiconductor layer and a light emitting layer, are constituted of organic substances. Organic devices, accordingly, are more flexible than inorganic devices with a functional layer made of an inorganic substance, and can be produced by a lower temperature process, so that a plastic substrate or a film can be used as their substrates, and as a result, they are lightweight and non-fragile devices.

Organic devices are made by applying or printing a solution containing an organic material, so that a large number of devices can be produced on a substrate large in area at low cost. Moreover, since there are a wide variety of organic materials which can be used as such a functional layer, devices widely varying in their characteristics can be produced by using organic materials differing in molecular structures.

In general, organic devices have a structure in which an organic layer, such as a functional layer made of an organic substance, is interposed between a negative electrode and a positive electrode. Since the conductivity of organic substances is inferior to that of metals, it is preferred in organic devices to form electrodes from metals. That is, it is preferred in the production of organic devices that electrodes containing metal are formed in contact with an organic layer made of an organic material.

In the production of organic devices, typically, a metal layer is formed first on the entire surface of an organic layer by sputtering, followed by patterning to remove a part of the metal layer where conductivity is unnecessary from the surface of the organic layer, thereby forming electrodes. Through such steps, there can be produced a product having a large number of devices on a substrate large in area in a convenient manner.

However, metal vapor used in sputtering has high energy and therefore may alter in quality the organic layer when it comes into contact therewith. In this case, the surface of the organic layer exposed by sputtering at the time of the formation of electrodes has been altered in characteristics compared with the original state before forming electrodes.

In patterning the metal layer, an etching solution containing a relatively strong alkali or acid is used in an etching or liftoff step. The strong alkali or strong acid contained in the etching solution may alter the underlying organic layer in some cases.

If the organic layer is altered by the action of metal vapor, strong acids, strong alkalis or the like, adverse effects are caused on functions of the organic layer and, eventually, on properties of the device, resulting in some problems. For example, in the case where an organic insulating material is used as a gate insulating layer of an organic thin film transistor, if a source electrode and a drain electrode are formed by directly depositing metal on the insulating layer to form a metal layer and then patterning this metal layer to form the electrodes, a hydrophilic surface of the gate insulating layer is exposed, so that transistor characteristics are deteriorated.

Patent Document 1 describes that the entire surface of a gate insulating layer of an organic thin film transistor is coated with a barrier layer having higher solvent resistance. Thanks to the presence of the barrier layer, the gate insulating layer as an organic layer is protected from action of, for example, an etching solution used in patterning a metal layer and an organic solvent used in forming an organic semiconductor layer, with the presence of the barrier layer.

Patent Document 1 describes that a preferable barrier layer is an insulating inorganic film formed by an application process or a vacuum process. A composition for forming the barrier layer is a solution prepared by dissolving polytitano-metalloxane in 1-butanol as specifically disclosed in Example.

However, polytitano-metalloxane is chemically highly stable, so that an extremely strong alkali solution is required in order to etch such a layer. When the strong alkali solution comes into contact with the underlying organic layer, it damages the surface of the organic layer. Therefore, the barrier layer made of polytitano-metalloxane according to Patent Document 1 has difficulty in being removed when it becomes unnecessary and being patterned, and the removal or patterning of the barrier layer results in damaging of the underlying gate insulating layer.

### BACKGROUND ART DOCUMENT

### Patent Document

Patent Document 1: WO2007/99689

### SUMMARY OF THE INVENTION

### Problems to be Solved by the Invention

The present invention is to solve the conventional problems described above, and an object thereof is to provide such an organic surface protective layer composition that a thin and uniform protective layer can be formed on a surface of an organic layer, that the formed protective layer can be removed easily by etching, and that it can inhibit the alteration of the surface of the organic layer exposed by the etching.

The “protective layer composition” refers to a composition for forming a protective layer. The “protective layer” refers to a layer that coats a surface which is a subject to be protected so as to protect the surface from influence of physical or chemical action applied from surroundings. Examples of the physical action include altering actions due to energy of metal vapor used in a physical vapor deposition (PVD) method. Examples of the chemical action include altering actions due to alkalis or acids used in etching.

### Means for Solving the Problems

The present invention provides an organic surface protective layer composition comprising (A) a metal alkoxide, (B) a stabilizer for the metal alkoxide and (C) an organic solvent capable of dissolving the metal alkoxide.

In one embodiment, the metal alkoxide is a tungsten alkoxide.

In one embodiment, the stabilizer for the metal alkoxide is one or more compounds selected from the group consisting of α-hydroxy ketones, α-hydroxy ketoimines, ethanolamines, α-diketones, α-diketoimines, β-diketones and α-hydroxycarboxylic acids.

In one embodiment, the organic solvent is an organic solvent having a fluorine atom.

In one embodiment, the organic solvent having a fluorine atom is an aromatic compound having a fluorine atom.

The present invention also provides a method for protecting a surface of an organic substance, the method comprising the steps of

applying any one of the organic surface protective layer compositions described above onto a surface of an organic substance;

curing the metal alkoxide contained in the organic surface protective layer composition by a sol-gel method to form an organic surface protective layer;

subjecting a surface of the organic surface protective layer to a treatment which alters the surface of the organic substance if this treatment is carried out directly onto the surface of the organic substance; and

removing the organic surface protective layer by etching.

The present invention also provides an organic layer having a surface protected by using the method described above.

The present invention also provides an organic thin film transistor gate insulating layer having a surface protected by using the method described above.

The present invention also provides an organic thin film transistor having the organic thin film transistor gate insulating layer described above.

### Effects of the Invention

The organic surface protective layer composition of the present invention can form a thin and uniform protective layer on the organic surface. In addition, the formed protective layer can be removed easily by etching, and the organic surface exposed by the etching remains unaltered.

### BRIEF DESCRIPTION OF THE DRAWINGS

FIG. 1A cross-sectional diagram illustrating the structure of an organic thin film transistor which is one embodiment of the present invention.

FIG. 2A cross-sectional diagram illustrating the structure of a laminated body to be formed in the process of producing the organic thin film transistor of FIG. 1.

FIG. 3A cross-sectional diagram illustrating the structure of a laminated body to be formed in the process of producing the organic thin film transistor of FIG. 1.

FIG. 4A cross-sectional diagram illustrating the structure of a laminated body to be formed in the process of producing the organic thin film transistor of FIG. 1.

FIG. 5A cross-sectional diagram illustrating the structure of a laminated body to be formed in the process of producing the organic thin film transistor of FIG. 1.

FIG. 6A cross-sectional diagram illustrating the structure of a laminated body to be formed in the process of producing the organic thin film transistor of FIG. 1.

FIG. 7A cross-sectional diagram illustrating the structure of a laminated body to be formed in the process of producing the organic thin film transistor of FIG. 1.

### MODE FOR CARRYING OUT THE INVENTION

### Organic Surface Protective Layer Composition

The organic surface protective layer composition of the present invention is a solution comprising a metal alkoxide (A), a stabilizer (B) for the metal alkoxide and an organic solvent (C) capable of dissolving the metal alkoxide. The organic surface protective layer composition of the present invention is prepared by mixing the constituent components. The mixing of the constituent components can be carried out by, for example, a method of charging these components into an appropriate container and stirring them.

Metal Alkoxide (A)

The metal alkoxide (A) is a compound for forming a protective layer containing polymetalloxane on an organic surface by a sol-gel method. This protective layer resists corrosion by metal vapor and blocks metal vapor. Such a protective layer is easily etched; therefore, a protective layer that has become unnecessary is easily removed from the organic surface. Examples of the metal alkoxide include a titanium alkoxide, an aluminum alkoxide, a tungsten alkoxide, a niobium alkoxide, a zirconium alkoxide, a vanadium alkoxide and a tantalum alkoxide.

A preferred metal alkoxide is a tungsten alkoxide.

In the case of etching or lifting-off a tungsten alkoxide layer, a solvent of an etching solution includes water or alcohol when the etching solution is relatively weak alkali. When the alkali contained in the etching solution is relatively weak, even if this comes into contact with the underlying organic surface, the organic surface remains unaltered.

Examples of the alkali contained in the etching solution include sodium carbonate, potassium carbonate, sodium hydroxide, potassium hydroxide, tetramethylammonium hydroxide and monoethanolamine.

Specific examples of the tungsten alkoxide include tungsten(V) methoxide, tungsten(V) ethoxide, tungsten(V) isopropoxide and tungsten(V) butoxide.

Stabilizer for Metal Alkoxide (B)

The stabilizer (B) for the metal alkoxide contained in the organic surface protective layer composition of the present invention is preferably one or more compounds selected from the group consisting of α-hydroxy ketones, α-hydroxy ketoimines, ethanolamines, α-diketones, α-diketoimines, α-hydroxycarboxylic acids and β-diketones.

Examples of the α-hydroxy ketones include acetol and acetoin.

Examples of the α-hydroxy ketoimines include acetol hydrazone.

Examples of the ethanolamines include monoethanolamine and diethanolamine.

Examples of the α-diketones include diacetyl.

Examples of the α-diketoimines include 2,3-{di(2′-hydroxyethylimino)}butane.

Examples of the α-hydroxycarboxylic acids include glycolic acid, lactic acid, 2-hydroxyisobutyric acid, mandelic acid and oxalic acid.

Examples of the β-diketones include acetylacetone.

In the case of using a metal alkoxide with high reactivity such as a tungsten alkoxide, a stabilizer with higher stabilization power is used. This makes it possible to form a thin and uniform protective layer. A particularly preferred stabilizer is acetylacetone.

Organic Solvent (C)

The organic solvent (C) is an organic solvent which is capable of dissolving the metal alkoxide to be used and preferably dissolving the stabilizer as well, and which is volatile at room temperature. An organic solvent having a fluorine atom is preferred because it has poor affinity with an organic substance and hardly causes adverse effects on the organic surface. The organic solvent having a fluorine atom is well compatible with the organic surface when the organic surface has a fluorine atom, and therefore it is advantageous to form a thin and uniform protective layer.

The organic solvent having a fluorine atom is, in particular, preferably an aromatic compound having a fluorine atom. The aromatic compound having a fluorine atom is well compatible with the organic surface when the organic surface has a fluoro-substituted aromatic moiety, and therefore it is advantageous to form a thin and uniform protective layer.

Examples of the aromatic compound having a fluorine atom include trifluoromethylbenzene, 2,3,4,5,6-pentafluorotoluene, octafluorotoluene, hexafluorobenzene and 2,3,4,5,6-pentafluorostyrene.

In the protective layer composition for an organic layer of the present invention, the number of moles of the metal alkoxide (A) is preferably from 10 to 90, and more preferably from 20 to 80 where the sum total of the number of moles of the metal alkoxide (A) and the number of moles of the stabilizer (B) of the metal alkoxide is 100.

Moreover, the weight of the organic solvent (C) having a fluorine atom is preferably from 25 to 3000, and more preferably from 100 to 2000 where the sum total of the weight of the metal alkoxide (A) and the weight of the stabilizer (B) of the metal alkoxide is 100.

### Method for Protecting Organic Surface

The method for protecting an organic surface of the present invention is carried out by first forming a protective layer on a surface of an organic substance and then removing the protective layer. In general, between the formation of the protective layer and the removal of the protective layer is carried out a step in which the surface of the protective layer is subjected to a treatment which alters the surface of the organic substance if this treatment is carried out directly onto the surface of the organic substance. For example, there is carried out a step of forming a metal layer above the organic surface, e.g., on the protective layer.

Examples of the step of forming a metal layer include a physical vapor deposition (PVD) method including a sputtering method and patterning accompanied by etching. That is, during the formation of the metal layer on the organic surface, the protective layer prevents the organic surface from being affected by physical or chemical action which is necessary for forming the metal layer.

The organic surface which is a subject to be protected is a surface of an organic substance, above which a metal layer such as electrode or wiring is to be formed. Examples of such an organic substance include a function layer and an insulating layer of an organic device.

More preferred is such an organic substance that protection of part of its organic surface is unnecessary after the metal layer is once formed. The reason for this is that since characteristics of the organic surface are maintained before and after the formation of the metal layer in the method for protecting an organic surface of the present invention, original characteristics and functions of the organic layer are exhibited even when the surface of the organic layer is exposed after the formation of the metal layer.

A particularly preferred organic substance whose surface is to be protected is a function layer of an organic device, in particular, an organic thin film transistor gate insulating layer. An organic thin film transistor having a gate insulating layer protected by the method of the present invention is excellent in transistor characteristics and in particular, small in hysteresis and the absolute value of threshold voltage.

The organic surface protective layer is formed by applying the organic surface protective layer composition of the present invention onto the surface of an organic substance and curing the metal alkoxide contained in the organic surface protective layer composition by a sol-gel method. When the metal alkoxide is highly reactive, the curing reaction of the metal alkoxide, which is a sol-gel reaction, is caused by moisture in the air.

Therefore, in the case of, for example, using a tungsten alkoxide as the metal alkoxide, a sol-gel reaction occurs by allowing an applied film of the organic surface protective layer composition to stand in the atmosphere, so that a protective layer is formed. Preferably, the applied film containing a tungsten alkoxide is allowed to stand in the atmosphere where humidity is adjusted within a prescribed range, and subjected to a sol-gel reaction.

In one embodiment, a step of forming a metal layer is carried out after the organic surface protective layer is formed.

After the metal layer is formed, in the case where protection of the organic surface has become no longer necessary or the organic surface has become required to be exposed, the protective layer is removed from the organic surface. The removal of the protective layer may be carried out partially. The removal of the protective layer can be carried out by etching with an etching solution suitable for removing the metal oxide formed to be used, for example, an alkali solution.

### EXAMPLES

The present invention is described below in more detail by way of Examples; however, the invention is not limited by the Examples.

It is to be noted that, in Examples, the contact angle to pure water of a gate insulating layer was measured with a contact angle meter, model “CA-A” (manufactured by Kyowa Interface Science Co., Ltd.). In measuring the contact angle, deionized water was used as the pure water.

### Synthesis Example 1

### Production of Macromolecular Compound 1

A 50-ml pressure-resistant container (produce by ACE) was charged with 2.06 g of styrene (produced by Wako Pure Chemical Industries, Ltd.), 2.43 g of 2,3,4,5,6-pentafluorostyrene (produced by Aldrich), 1.00 g of 2-[O-[1′-methylpropylideneamino]carboxyamino]ethyl methacrylate (produced by Showa Denko K.K., commercial name “Karenz MOI-BM”), 0.06 g of 2,2′-azobis(2-methylpropionitrile), and 14.06 g of 2-heptanone (produced by Wako Pure Chemical Industries, Ltd.) and was sealed tightly after bubbling with nitrogen. Polymerization was carried out in an oil bath of 60° C. for 48 hours, so that a viscous 2-heptanone solution containing macromolecular compound 1 dissolved therein was obtained. The macromolecular compound 1 has the following repeating units. Here, subscript numbers of parentheses denote molar fractions of repeating units.

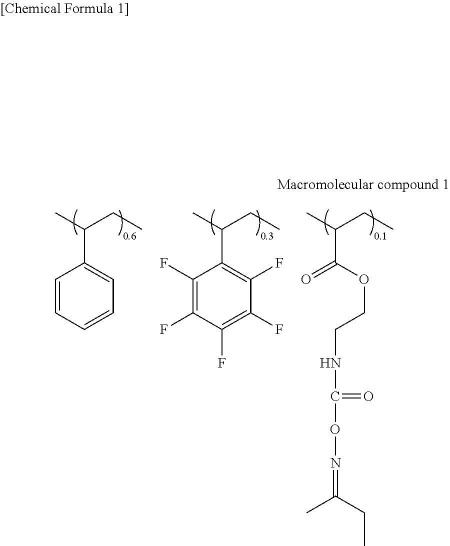

The weight average molecular weight of the resulting macromolecular compound 1 calculated from standard polystyrene was 32800 (measurement conditions: GPC manufactured by Shimadzu Corporation, one “Tskgel super HM-H” column and one “Tskgel super H2000” column, mobile phase=THF).

The macromolecular compound 1 is excellent in insulating characteristics and useful as an insulating material of an organic device or a material for forming an insulating layer, particularly an organic thin film transistor gate insulating layer.

### Example 1

### Production of Organic Surface Protective Layer Composition

Into a 10-ml sample bottle were charged 1.30 g of tungsten(V) ethoxide (produced by Gelest, Inc.), 0.32 g of acetylacetone (produced by Wako Pure Chemical Industries, Ltd.) as a stabilizer for the metal alkoxide, and 4.00 g of 2,3,4,5,6-pentafluorotoluene, which were then mixed while stirring to prepare a homogeneous application liquid as an organic surface protective layer composition.

### (Production of Organic Layer and Measurement of Contact Angle)

Into a 10-ml sample bottle were charged 3.00 g of the 2-heptanone solution of the macromolecular compound 1 obtained in Synthesis Example 1, 0.091 g of 1,3-bis(3′-aminophenoxy)benzene and 1.50 g of 2-heptanone, which were then mixed while stirring to prepare a homogeneous solution.

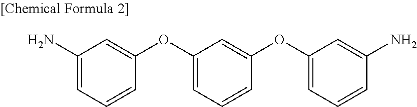

### 1,3-bis(3′-aminophenoxy)benzene

The resulting solution was filtered through a membrane filter having a pore diameter of 0.2 μm, and the filtrate was applied onto a glass substrate by spin coating, and then baked on a hot plate at 220° C. for 30 minutes to obtain an organic layer. The contact angle to pure water of the organic layer was 92°.

### (Formation of Organic Surface Protective Layer)

Next, the organic surface protective layer composition was filtered through a membrane filter having a pore diameter of 0.2 μm, and the filtrate was applied onto the organic layer by spin coating, and then baked on a hot plate at 150° C. for 30 minutes to obtain an organic surface protective layer of about 20 nm in thickness.

(Measurement of Contact Angle of Organic Layer after Formation of Electrode)

Then, molybdenum as an electrode material was laminated on the organic surface protective layer by sputtering. The laminated molybdenum was then etched with a molybdenum etching solution and thereby removed. The organic surface protective layer was thereafter removed with an alkaline etching solution to expose the surface of the organic layer. Here, as the alkaline etching solution, “Melstrip TI-3991” (produced by Meltex Inc.) was used.

The contact angle to pure water of the exposed organic layer was 89.5°, and the change in contact angle to pure water of the organic layer resulting from the formation of the electrode was 2.5°.

### Comparative Example 1

An organic layer was produced in the same manner as in Example 1. The contact angles to pure water of the organic layer before the formation of the electrode and after the removal of the electrode were then measured in the same manner as in Example 1, except that no organic surface protective layer was formed. The contact angle to pure water of the organic layer after the removal of the electrode was 25°, and the change in contact angle to pure water of the organic layer resulting from the formation of the electrode was 64.5°, which showed that sputtering damage was high.

TABLE 1

| | Contact angle of organic layer | | |
|---|---|---|---|
| | Immediately | | After removal |
| | after formation | After removal of | of protective |
| | of organic layer | electrode | layer |
| Example 1 | 92° | — | 89.5° |
| Comparative | 92° | 25° | — |
| Example 1 | | | |

As shown in the result of Example, according to the present invention, an organic thin film transistor gate insulating layer can be provided, which has little sputtering damage even when an electrode material is formed by sputtering.

### Example 2

### Production of Organic Surface Protective Layer Composition

Into a 10-ml sample bottle were charged 1.30 g of tungsten(V) ethoxide (produced by Gelest, Inc.), 0.32 g of acetylacetone (produced by Wako Pure Chemical Industries, Ltd.) as a stabilizer for the metal alkoxide, and 4.00 g of PGMEA (propylene glycol monomethyl ether acetate), which were then mixed while stirring to prepare a homogeneous application liquid as an organic surface protective layer composition.

### Synthesis Example 2

### Synthesis of Macromolecular Compound 2

A 125-ml pressure-resistant container (produce by ACE) was charged with 3.50 g of 4-aminostyrene (produced by Aldrich), 13.32 g of 2,3,4,5,6-pentafluorostyrene (produced by Aldrich), 0.08 g of 2,2′-azobis(2-methylpropionitrile), and 25.36 g of 2-heptanone (produced by Wako Pure Chemical Industries, Ltd.) and was sealed tightly after bubbling with nitrogen. Polymerization was carried out in an oil bath of 60° C. for 48 hours, so that a viscous 2-heptanone solution containing macromolecular compound 2 dissolved therein was obtained. The macromolecular compound 2 has the following repeating units. Here, subscript numbers of parentheses denote molar fractions of repeating units.

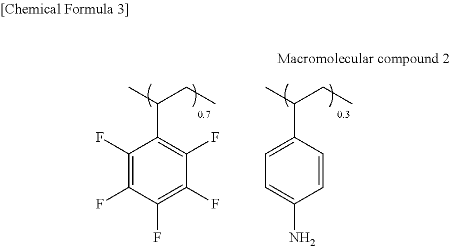

The weight average molecular weight of the resulting macromolecular compound 2 calculated from standard polystyrene was 132000 (measurement conditions: GPC manufactured by Shimadzu Corporation, one “Tskgel super HM-H” column and one “Tskgel super H2000” column, mobile phase=THF).

### Synthesis Example 3

### Synthesis of Macromolecular Compound 3

To toluene (80 mL) containing 6.40 g of 9,9-di-n-octylfluorene-2,7-di(ethyleneboronate) and 4.00 g of 5,5′-dibromo-2,2′-bithiophene were added under nitrogen 0.18 g of tetrakis(triphenylphosphine)palladium, 1.0 g of methyltrioctylammonium chloride (produced by Aldrich, commercial name “Aliquat 336” (registered trademark)), and 24 mL of 2M aqueous sodium carbonate solution. The resulting mixture was stirred vigorously and heated to reflux for 24 hours. A viscous reaction mixture was poured into 500 mL of acetone, so that fibrous yellow polymer was precipitated. This polymer was collected by filtration, washed with acetone, and dried at 60° C. in a vacuum oven overnight. The resulting polymer is called macromolecular compound 3. The macromolecular compound 3 has the following repeating units. Here, n denotes the number of repeating units. The weight average molecular weight of the macromolecular compound 3 calculated from standard polystyrene was 61000 (measurement conditions: GPC manufactured by Shimadzu Corporation, one “Tskgel super HM-H” column and one “Tskgel super H2000” column, mobile phase=THF).

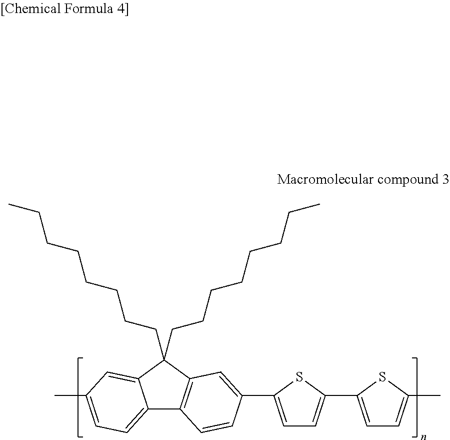

### Example 3

### Production of Organic Thin Film Transistor

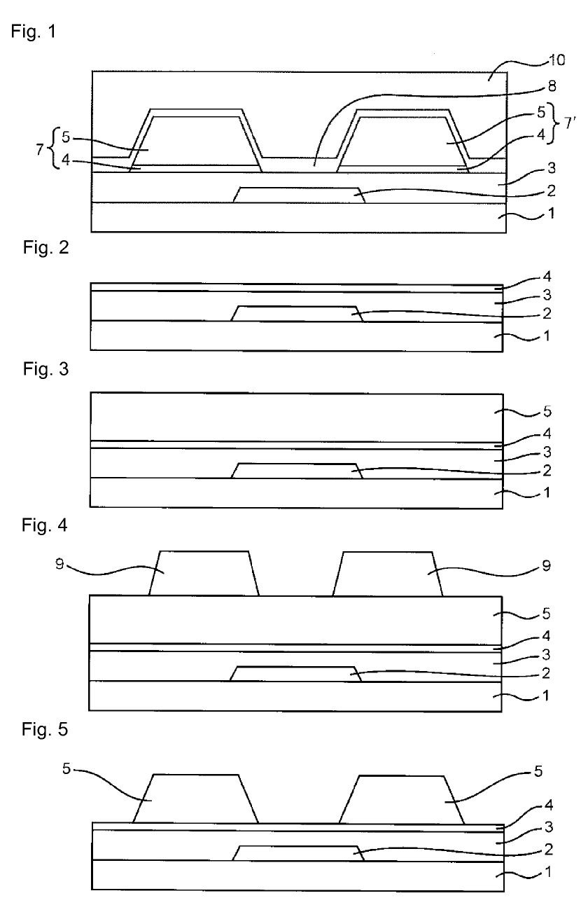

An Example of the organic thin film transistor of the present invention is described by way of FIG. 1 to FIG. 7.

In this Example, an organic thin film transistor was produced by preparing a substrate (glass) 1; a gate electrode (Mo) 2 on the substrate 1; a gate insulating film (an organic insulating film) 3 on the gate electrode 2; a pair of electrodes each comprised of a first conductive layer 4 and a second conductive layer 5 (one is referred to as a source electrode 7 and the other is referred to as a drain electrode 7′) on the gate insulating film 3; and subsequently forming an organic semiconductor layer 8 covering the source electrode 7 and the drain electrode 7′.

As to the produced organic thin film transistor, transistor characteristics were measured in a vacuum prober, and a comparison of the characteristics was made to confirm the effect of the present invention. The pressure in the vacuum prober at this time was about 5E-3 Pa.

Next, a process of producing the device of the present invention is described.

First, a Mo (molybdenum) layer was formed by sputtering on a substrate 1 which had been washed, and a gate electrode 2 was formed by photolithography. In the photolithography, a photoresist “TFR-H PL” produced by TOKYO OHKA KOGYO CO., LTD, a developer “NPD-18” produced by Nagase ChemteX Corporation, a resist stripper “106” produced by TOKYO OHKA KOGYO CO., LTD and a Mo etching liquid “S-80520” produced by KANTO CHEMICAL CO., INC were used. The photolithography was carried out by the following steps. A film of the photoresist “TFR-H PL” was formed on the Mo layer and irradiated with UV light of 365 nm through a photomask. The photoresist was then developed with the developer “NPD-18”. The developed photoresist was then used as a mask, and the part of the Mo layer where Mo was exposed was removed with the Mo etching liquid “S-80520”. The remaining photoresist was then stripped with the resist stripper “106”, and thus a gate electrode 2 was patterned.

Next, the substrate on which the gate electrode 2 was formed was subjected to washing in a wet manner and thereafter washed with a UV ozone cleaner for 300 seconds. A solution containing the macromolecular compound 1, the macromolecular compound 2 and 2-heptanone was then applied onto a gate insulating layer by spin coating to form an organic layer. Since this organic layer was thermally-crosslinkable, it was immediately subjected to a baking treatment to obtain a gate insulating layer 3. As a final baking treatment at this time, baking was carried out at 220° C. for 25 minutes. The gate insulating layer 3 had a layer thickness of about 470 nm.

Then, the organic surface protective layer composition produced in Example 2 was applied onto the gate insulating layer 3 by spin coating. After the application, this was dried in the atmosphere for about 5 minutes and then subjected to a baking treatment at 150° C. for 30 minutes to obtain a first conductive layer 4 (organic surface protective layer) shown in FIG. 2. In order to obtain the layer thickness of the first conductive layer 4, this composition was applied onto a glass substrate in advance under the same conditions, and the thus-formed layer had a layer thickness of 30 nm.

Thereafter, a copper (Cu) layer was formed on the first conductive layer 4 in a layer thickness of 100 nm by sputtering to obtain a second conductive layer 5 shown in FIG. 3. Thereafter, the second conductive layer was processed by photolithography, through the configuration in FIG. 4, into the shape of the second conductive layer 5 shown in FIG. 5. In the photolithography, a photoresist “TFR-H PL” produced by TOKYO OHKA KOGYO CO., LTD, a developer “NPD-18” produced by Nagase ChemteX Corporation, a resist stripper “106” produced by TOKYO OHKA KOGYO CO., LTD and a Cu etching liquid, mixed acid “Cu-03” produced by KANTO CHEMICAL CO., INC were used. The photolithography was carried out by the following steps. A film of the photoresist “TFR-H PL” was formed on the Cu layer and irradiated with UV light of 365 nm through a photomask. The photoresist was then developed with the developer “NPD-18”. The developed photoresist was then used as a mask, and the part of the second conductive layer 5 where Cu was exposed was removed with the Cu etching liquid “Cu-03”. The remaining photoresist was then stripped with the resist stripper “106”, and thus the second conductive layer 5 was patterned.

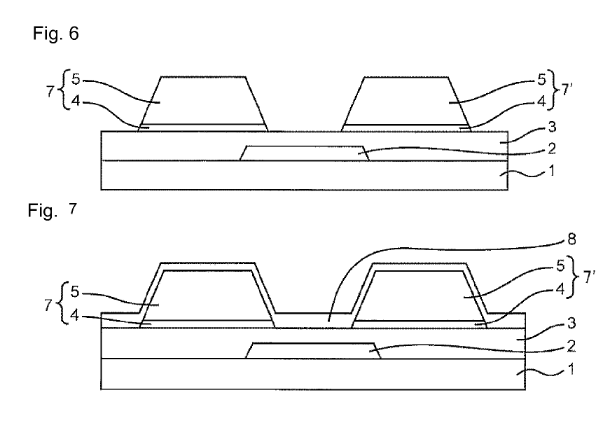

The patterned second conductive layer 5 was then used as a mask, and the part of the first conductive layer 4 where not covered with the second conductive layer 5 (exposed part) was etched with an aqueous tetramethylammonium hydroxide solution (an aqueous TMAH solution: concentration 2.38%) to obtain an device structure shown in FIG. 6. The etching time at this time was 90 seconds.

By providing the first conductive layer 4, the surface of the gate insulating layer 3 can be protected from processing damage in producing the second conductive layer 5. Furthermore, by providing the first conductive layer 4, the adherence between the gate insulating layer 3 and the second conductive layer 5 is improved. The first conductive layer also functions as a protective layer against diffusion of the second conductive layer 5 to the gate insulating layer 3.

Next, as an organic semiconductor layer 8, the macromolecular compound 3 was dissolved in a xylene solution at a concentration of 0.5 wt %, and this was applied onto the substrate by spin coating in a glove box under a nitrogen atmosphere and subjected to a baking treatment at 200° C. for 10 minutes immediately after the application. At this time, the organic semiconductor layer had a layer thickness of about 16 nm. In this manner, an organic thin film transistor having a structure shown in FIG. 7 was obtained. In addition, the source electrode and the drain electrode were not subjected to a surface treatment at this time.

Thereafter, as transistor characteristics, transfer (Vg−Id) characteristics of 20 to −40V and output (Vd−Id) characteristics of 0 to −40V were measured with a vacuum prober. At this time, the vacuum prober had a degree of vacuum of about 5E-3 Pa. The transistor characteristics are shown in Table 2.

The gate insulating layer surface roughness Ra of the gate insulating layer was measured with a scanning probe microscope (manufactured by SII NanoTechnology Inc., trade name “SPI3800N”). The gate insulating layer surface contact angle was measured with an automatic contact angle measuring instrument (manufactured by EKO INSTRUMENTS Co., Ltd., trade name “OCA20”). Mobility μ, maximum current Ion, threshold voltage Vth, hysteresis, swing factor (sub-threshold swing), on/off ratio were calculated from the transfer (Vg−Id) characteristics. Here, the voltage of starting weak inversion region formation in which the drain current Id of the transfer (Vg−Id) characteristics rises is defined as the drain current rising voltage Von, which is shown in Table 2 aside from the threshold voltage Vth.

### Comparative Example 2

As a Comparative Example for Example 3, an organic thin film transistor was produced by preparing a substrate (glass) 1; a gate electrode (Mo) 2 on the substrate 1; a gate insulating layer (an organic insulating layer) 3 on the gate electrode 2; a source electrode and a drain electrode each comprised of a single layer which is a single metal layer of the same material as that of the second conductive layer 5 in Example 3, on the gate insulating layer 3; and subsequently forming an organic semiconductor layer covering the source electrode and the drain electrode.

That is, the organic thin film transistor is produced in the same manner as in Example 3, except that the first conductive layer 4 was not formed, and the second conductive layer 5 was formed on the gate insulating layer 3 and patterned by photolithography to form the source electrode and the drain electrode. Then, transistor characteristics were measured. The resulting transistor characteristics are shown in Table 2.

### Reference Example

In the same manner as in Example 3, a gate electrode 2 was formed on a substrate 1, and a gate insulating layer 3 was formed on the gate electrode. The gate insulating layer surface roughness Ra and gate insulating layer surface contact angle of the gate insulating layer were measured. The results are shown in the column of “gate insulating layer without undergoing the process” in Table 2.

TABLE 2

| | Example | | |
|---|---|---|---|
| | Gate insulating | | |
| | layer without | | |
| | undergoing the | Comparative | |
| | process | Example 2 | Example 3 |
| Film thickness of Cu layer | — | 100 | 100 |
| [nm] | | | |
| Gate insulating film surface | 0.5535 | 1.232 | 0.7243 |
| roughness Ra [nm] | | | |
| Gate insulating film surface | 94.8 | 66.4 | 90.5 |
| contact angle [°] | | | |
| Mobility μ [cm²/Vs] | — | 2.46E−04 | 5.31E−03 |
| Maximum current Ion [A] | — | 2.16E−09 | 1.24E−07 |
| Threshold voltage Vth [V] | — | −12.00 | −8.00 |
| Drain current rising voltage | | −12.50 | −1.00 |
| Von [V] | | | |
| Hysteresis [V] | | 5.00 | 0.50 |
| Sub-threshold swing | — | 1.44 | 0.69 |
| [V/decade] | | | |
| ON/OFF ratio | — | 1.00E+03 | 1.60E+05 |

This shows that the organic thin film transistor of Example 3 is improved in all transistor characteristics compared with the organic thin film transistor of Comparative Example 2. As to the surface roughness and surface contact angle of the gate insulating layer 3, the organic thin film transistor of Example 3 receives significantly reduced processing damage to the gate insulating layer in forming the Cu layer by sputtering and shows equivalent values to those of Reference Example which is the gate insulating layer without undergoing the process. The organic thin film transistor of Comparative Example 2 shows, in the surface roughness and surface contact angle of the gate insulating layer 3, significant influence of physical damage to the gate insulating layer, since the Cu layer is formed on the organic insulating layer directly by high-power sputtering.

Compared with the organic thin film transistor of Comparative Example 2, the organic thin film transistor of Example 3 has a drain current rising voltage Von of nearly 0 [V], little hysteresis and a maximum current Ion of about 2 orders of magnitude improved.

### DESCRIPTION OF REFERENCE NUMERALS

1: Substrate
2: Gate electrode
3: Gate insulating layer
4: First conductive layer
5: Second conductive layer
7: Source electrode
7′: Drain electrode
8: Organic semiconductor layer
9: Mask
10: Protective layer

1. An organic surface protective layer composition comprising (A) a metal alkoxide, (B) a stabilizer for the metal alkoxide and (C) an organic solvent capable of dissolving the metal alkoxide.

2. The organic surface protective layer composition according to claim 1, wherein the metal alkoxide is a tungsten alkoxide.

3. The organic surface protective layer composition according to claim 1, wherein the stabilizer for the metal alkoxide is one or more compounds selected from the group consisting of α-hydroxy ketones, α-hydroxy ketoimines, ethanolamines, α-diketones, α-diketoimines, β-diketones and α-hydroxycarboxylic acids.

4. The organic surface protective layer composition according to claim 1, wherein the organic solvent is an organic solvent having a fluorine atom.

5. The organic surface protective layer composition according to claim 4, wherein the organic solvent having a fluorine atom is an aromatic compound having a fluorine atom.

6. A method for protecting a surface of an organic substance, the method comprising the steps of:
applying the organic surface protective layer composition according to claim 1 onto a surface of an organic substance;
curing the metal alkoxide contained in the organic surface protective layer composition by a sol-gel method to form an organic surface protective layer;
subjecting a surface of the organic surface protective layer to a treatment which alters the surface of the organic substance if this treatment is carried out directly onto the surface of the organic substance; and
removing the organic surface protective layer by etching.

7. An organic layer having a surface protected by using the method according to claim 6.

8. An organic thin film transistor gate insulating layer having a surface protected by using the method according to claim 6.

9. An organic thin film transistor having the organic thin film transistor gate insulating layer according to claim 8.
